(19) United States
(12) Patent Application Publication
(10) Pub. No.: US 2017/0338363 A1
(43) Pub. Date: Nov. 23, 2017

(54) IMPACT RESISTANT LIGHTWEIGHT PHOTOVOLTAIC MODULES

(71) Applicant: Solexel, Inc., Milpitas, CA (US)

(72) Inventors: Anjuli WRIGHT, Milpitas, CA (US); Eric J. LEE, Milpitas, CA (US)

(21) Appl. No.: 15/525,513

(22) PCT Filed: Nov. 10, 2015
(86) PCT No.: PCT/US2015/060046

§ 371 Date: May 9, 2017

Related U.S. Application Data
(60) Provisional application No. 62/077,878, filed on Nov. 10, 2014.

(51) Int. Cl. H01L 31/048; H01L 31/049

(52) U.S. Cl. CPC H01L 31/0481; H01L 31/049

(57) ABSTRACT

A photovoltaic module structure comprises a transparent front encapsulant and a back encapsulant encapsulating a solar cell. The transparent front encapsulant has an elastic modulus lower than or equal to 30 megapascals and the back encapsulant has an elastic modulus greater than or equal to 100 megapascals. A module backplane is attached to the back encapsulant. The module backplane has a flexural rigidity of a plate greater than or equal to 6 Newton meters.

### CROSS-REFERENCE TO RELATED APPLICATIONS

This application claims the benefit of U.S. provisional patent application 62/077,878 filed on Nov. 10, 2014, which is hereby incorporated by reference in its entirety.

### FIELD OF THE INVENTION

The present disclosure relates in general to the fields of solar photovoltaics (PV), and more particularly to solar photovoltaic module structures and fabrication methods.

### BACKGROUND

The effects from weather and wear in field use to photovoltaic solar cells and modules, or solar cells and modules, due to, for example, mechanical impacts from hail, falling tree branches, and in some instances walking on modules may lead to costly damage such as cracking and electrical power loss. Many solar cell absorber materials, such as crystalline silicon, are particularly brittle and impact sensitive—characteristics which may be further exacerbated dependent on the solar cell absorber thickness.

To protect solar cells without reducing power, current photovoltaic solar modules often rely on materials such as glass or often expensive thick, heavy, and/or rigid materials which may provide sufficient impact protection but also may limit certain solar cell application, for example to areas capable of withstanding and supporting heavier solar module structures. Additionally, these module materials may be temperature sensitive such that their effectiveness and impact strength is reduced outside of a certain temperature range. On the other hand, lighter weight photovoltaic solar modules often use flexible frontsheet and backsheet in the module construction, for example a thin fluoropolymer frontsheet and a poly-ethylene terephthalate (PET) based backsheet. However, often this lightweight module packaging construction does not provide the required impact protection for brittle semiconductor (e.g., silicon) solar cells. For example, in traditional lightweight solar module packaging, the backsheet may be too flexible thus allowing the solar cell and semiconductor absorber to deform relatively easily and crack, and the front encapsulant layer may be too thin thus providing too little cushioning to protect the solar cell and particularly the semiconductor absorber (e.g., silicon absorber). However, numerous factors must be considered and balanced to provide photovoltaic solar module impact improvement and innovation.

### BRIEF SUMMARY OF THE INVENTION

Therefore, a need has arisen for lighter weight photovoltaic module structure with improved impact resistance. In accordance with the disclosed subject matter, photovoltaic module structures are provided which may substantially eliminate or reduces disadvantage and deficiencies associated with previously developed photovoltaic module structures.

According to one aspect of the disclosed subject matter, an impact resistant light weight photovoltaic module is provided. A photovoltaic module structure comprises a transparent front encapsulant and a back encapsulant encapsulating a solar cell. The transparent front encapsulant has an elastic modulus lower than or equal to 30 megapascals and the back encapsulant has an elastic modulus greater than or equal to 100 megapascals. A module backplane is attached to the back encapsulant. The module backplane has a flexural rigidity of a plate greater than or equal to 6 Newton meters.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a cross-sectional diagram of an embodiment of a high impact resistant glassless solar module with a backplane supported solar cell; and

FIG. 2 is a cross-sectional diagram of an embodiment of a high impact resistant glassless solar module with a backplane supported solar cell.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like aspects and identifiers being used to refer to like and corresponding parts of the various drawings.

And although the present disclosure is described with reference to specific embodiments, components, and materials, such as module encapsulants (transparent or otherwise), adhesive layers, planarizing layers, module backside backsheets, module frontside frontsheets, frontside cover sheets, and module backplanes, one skilled in the art could apply the principles discussed herein to other solar module structures, fabrication processes, as well as alternative technical areas and/or embodiments without undue experimentation.

Improved impact resistant, lighter weight, and semi-flexible solar photovoltaic module structures and fabrication methods are provided. These module solutions provide improved impact strengthening and resistance without performance or power loss, may be implemented as glassless solar module structures, and may be advantageously applicable to relatively mechanically brittle solar cells (e.g., crystalline semiconductor solar cells using absorber materials such as crystalline silicon). Also advantageously, the photovoltaic solar module framework solutions disclosed provide the required superior impact protection for thin silicon solar cells (e.g., solar cells having a silicon absorber thickness less than 150 μm and in some instances having a thickness less than 100 μm).

Present application provides a light weight and impact resistant solar module structural solution having a transparent front encapsulant, a back encapsulant, and a module backplane. Structural solutions include, but are not limited to, a relatively rigid module backplane, a relatively thicker front encapsulant having a low elastic modulus, and a relatively thinner back encapsulant having a high elastic modulus. Impact resistance may be measured by the joules a module structure or stack may absorb before damage to the cell is observed. For example, impact energy in a solar module hail test is often two joules. However, the module structural solution provided may absorb six joules before cell damage is observed. In other words, the module structure provided may be utilized without relatively heavy module materials (e.g., glass) while minimizing the effects of module frontside impacts.

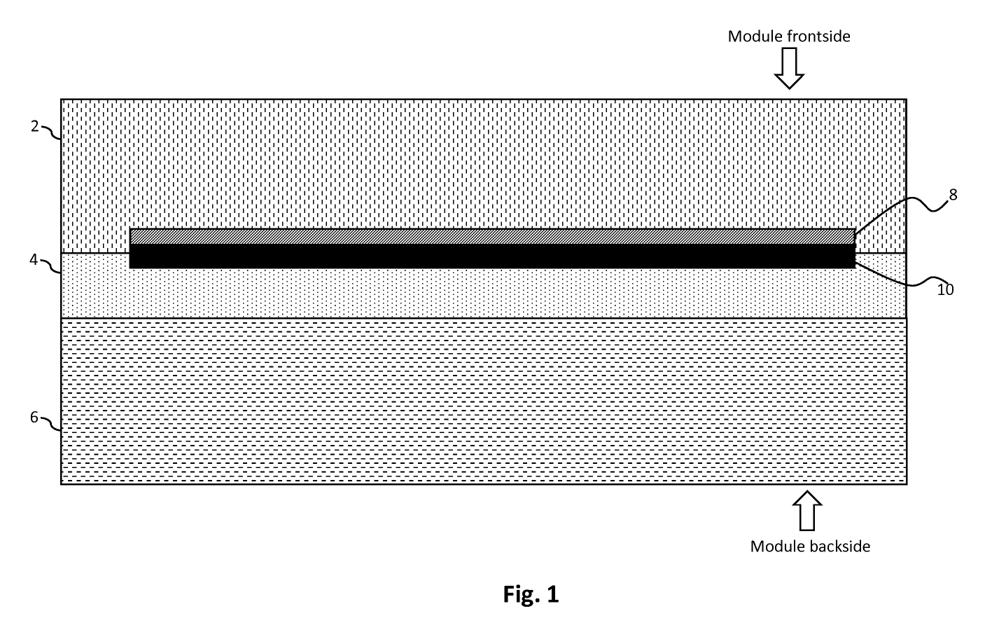

FIG. 1 is a cross-sectional diagram of a high impact resistant glassless solar module with a backplane supported solar cell. Solar cell 8 (e.g., a silicon solar cell such as a crystalline silicon solar cell) is attached to backplane 10 (e.g., a supportive backplane formed of a material such as prepreg) and encapsulated on the solar cell frontside by transparent front encapsulant 2 (e.g., having a thickness in the range of approximately 0.8 to 1.5 mm) and on the solar cell backside by back encapsulant 4 (e.g., having a thickness in the range of approximately 0.2 to 0.45 mm) which is attached to module backplane 6 (e.g., having a thickness in the range of approximately less than or equal to 1.5 mm but may be thicker if needed, for example 3 mm or thicker, with minimal effect to impact resistance). Front encapsulant 2, back encapsulant 4, module backplane 6 may be attached together using adhesion or pressure and heat, for example vacuum lamination of a sheet material lamination stack with a lamination process temperature of approximately 140° C. to 170° C. (e.g., a back encapsulant sheet, a front encapsulant sheet, and a module backplane sheet). The solar module of FIG. 1 may also have a thin weatherable transparent frontsheet layer (e.g., a fluoropolymer such as ethylene-tetrafluoroethylene ETFE) on the frontside (i.e., sunnyside) of transparent front encapsulant 2.

Descriptions of a transparent front encapsulant, a back encapsulant, and a module backplane are provided as structural guidelines for an impact resistant solar module structure. Additional considerations for a specific module material or construction choice may include material weight, chemical compatibility of encapsulants with solar cell layers or solar cell metallization, transparency or long-term UV stability of different encapsulant types, and fabrication considerations such as the effects of lamination (e.g., lamination temperature) on the material.

Front encapsulant 2 is a low elastic modulus encapsulant (e.g., a sheet) which acts as a cushion or cushioning layer to absorb impact energy by deforming. The front encapsulant may be a relatively thicker layer as impact resistance may be increased with material thickness. The majority of the deformation from impact should occur in the front encapsulant to avoid transferring the deflection to the solar cell below. An encapsulant with a higher elastic modulus will deform less, thereby transferring the force through to the solar cell causing solar cell cracking. For example, the front encapsulant may have an elastic modulus less than or equal to approximately 30 megapascals (MPa) and a thickness greater than or equal to 500 μm. Additionally, the front encapsulant may retain its cushioning properties with an addition of distributed glass frit or fiberglass scrim.

Back encapsulant 4 is an encapsulant (e.g., a sheet) between the module backplane and the solar cell which may provide adhesion for attachment of the module backplane as well as acts as a planarizing layer to planarize the solar cell or solar cells for module backplane attachment. Back encapsulant 4 may be a layer of high elastic modulus encapsulant behind the solar cell to support the semiconductor absorber (e.g., silicon) during impact. Back encapsulant 4 may be relatively rigid (e.g., a thin or thicker encapsulant having a higher elastic modulus) to further support the solar cell absorber (e.g., a silicon absorber) to prevent and/or reduce bending and deformation under impact. For example, the back encapsulant may have an elastic modulus greater than or equal to approximately 100 MPa. For highest impact resistance, the back encapsulant may be thinner, for example having a thickness less than or equal to 500 μm. However, in some instances the back encapsulant may be thicker, for example if necessitated by the solar cell backside topography (e.g., solar cell backside topography such as electrodes, metallization, electronic components, bussing or interconnection ribbons, etc.). Thus, while a soft thinner back encapsulant may reduce impact resistance, a thinner back encapsulant having an elastic modulus greater than or equal to approximately 100 MPa further reduces the impact resistance of the module structure.

Module backplane 6 is a relatively rigid (e.g., having a flexural rigidity greater than a threshold value) backplane (e.g., a sheet) attached to the back encapsulant which provides mechanical support to the solar cell to prevent or otherwise mitigate the solar cell from excessively deforming under load or impact and generating cracks. Thus, the module backplane prevents or reduces excessive deformation of the solar cell (e.g., silicon solar cell) during impact. Flexural rigidity of a plate, D, is a function of backplane material properties and backplane (plate) thickness, and be described as:

$$D = \frac{{Eh}^{3}}{12 ( 1 - {v}^{2} )}$$

$$E = Elastic Modulus$$

$$h = plate ( backplane ) thickness$$

$$v = Poisson ' s ratio$$

The module backplane, for example, may have a flexural rigidity of a plate greater than or equal to 6 Newton meters (Nm). For example, a module backplane of fiberglass-reinforced plastic (FRP) may have a thickness greater than approximately 1.5 mm and a module backplane of hard plastic may have a thickness greater than 3 mm. As fiber reinforcement may increase module backplane fracture strength, glass fiber reinforced plastic such as FR4 glass reinforced epoxy laminate sheet may be advantageous as a module backplane. Additionally, in some instances brittleness may be considered when selecting a module backplane material.

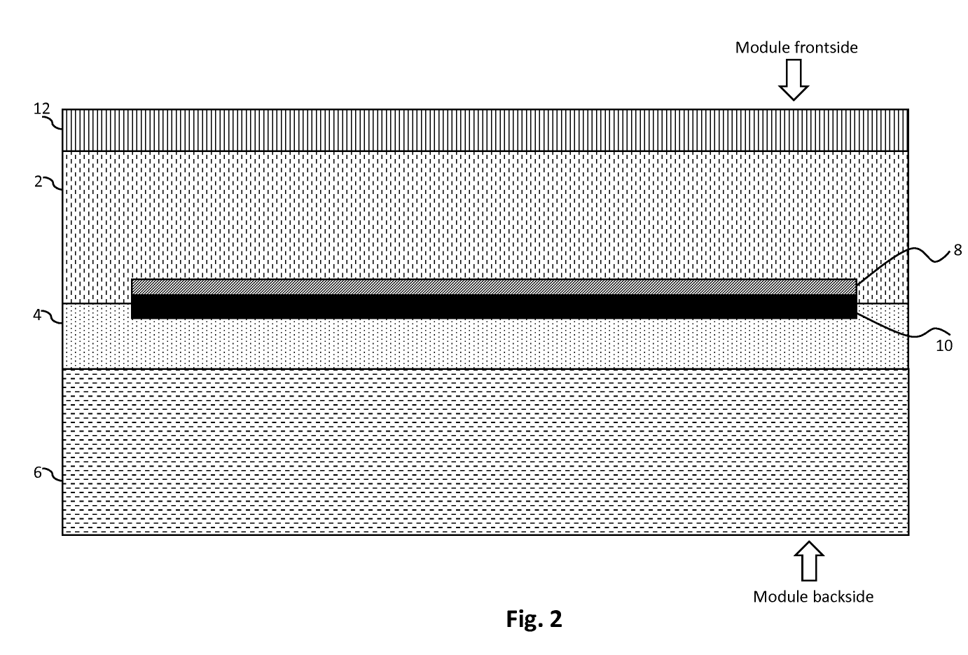

FIG. 2 is a cross-sectional diagram of a high impact resistant glassless solar module with a backplane supported solar cell consistent with FIG. 1 and including transparent top layer 12 (e.g., having a thickness in the range of approximately 0.5 to 1.5 μm) attached to front encapsulant 2. Top layer 12 provides weather protection and may be a film (e.g., a fluoropolymer film) having a thickness in the range of 50 to 150 μm.

Table 1 below shows examples of specific module constructions. With reference to FIG. 2, Table 1 shows materials for top layer 12, front encapsulant 2, back encapsulant 4, and module backplane 6. Encapsulant A in Table 1 is a cross-linking polyolefin or Ethylene-vinyl acetate (EVA) having an elastic modulus of approximately 25 MPa. Encapsulant B in Table 1 is a polyolefin having an elastic modulus approximately 160 MPa. Note ETFE stands for ethylene-tetrafluoroethylene.

| Layer | Example 1 | Example 2 | Example 3 | Example 4 |
|---|---|---|---|---|
| Top Layer | ETFE, | ETFE, | ETFE, | ETFE, 50 μm |
| | 50 μm | 50 μm | 50 μm | |
| Front | Encapsulant | Encapsulant | Encapsulant | Encapsulant |
| Encapsulant | A, 900 μm | A, 1350 μm | A, 900 μm | A, 900 μm |
| Back | Encapsulant | Encapsulant | Encapsulant | Encapsulant |
| Encapsulant | B, 400 μm | A, 450 μm | A, 200 μm | A, 200 μm |
| Module | FR4, 1.5 mm | FR4, 1.5 mm | FR4, 1.5 mm | Acrylic, 3 mm |
| Backplane | | | | |

Alternative construction elements that may provide improved impact resistance to a lesser degree may include: an approximately 3 mm-thick polycarbonate module backplane; an FR4 module backplane with thickness of in the range of approximately 0.8 to 1.2 mm; a front encapsulant having a standard thickness with a thin back encapsulant (e.g., having a thickness in the range of approximately 200 μm); or a thick front encapsulant with a 50 μm PET midsheet in the middle of the front encapsulant.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

1. A photovoltaic module structure, comprising:
a transparent front encapsulant and a back encapsulant encapsulating a solar cell, said transparent front encapsulant having an elastic modulus lower than or equal to 30 megapascals, said back encapsulant having an elastic modulus greater than or equal to 100 megapascals; and,
a module backplane attached to said back encapsulant, said module backplane having a flexural rigidity of a plate greater than or equal to 6 Newton meters.

2. The photovoltaic module structure of claim 1, wherein said transparent front encapsulant has a thickness greater than or equal to approximately 500 μm.

3. The photovoltaic module structure of claim 1, wherein said back encapsulant has a thickness less than or equal to approximately 500 μm.

4. The photovoltaic module structure of claim 1, wherein said module backplane is a fiber-reinforced backplane.

5. The photovoltaic module structure of claim 1, further comprising a transparent protective film attached to said front encapsulant, said transparent protective film having a thickness less than approximately 150 μm.

6. A photovoltaic module structure, comprising:
a transparent front encapsulant and a back encapsulant encapsulating a solar cell, said transparent front encapsulant having an elastic modulus lower than or equal to 30 megapascals and a thickness greater than or equal to approximately 500 μm, said back encapsulant having an elastic modulus greater than or equal to 100 megapascals and a thickness less than or equal to approximately 500 μm; and,
a module backplane attached to said back encapsulant, said module backplane having a flexural rigidity of a plate greater than or equal to 6 Newton meters.

7. The photovoltaic module structure of claim 6, further comprising a transparent protective film attached to said front encapsulant, said transparent protective film having a thickness less than approximately 150 μm.

8. A photovoltaic module structure, comprising
a transparent front encapsulant and a back encapsulant encapsulating a solar cell, said transparent front encapsulant having an elastic modulus between about 25 megapascals and about 30 megapascals, said back encapsulant having an elastic modulus between about 100 megapascals and about 160 megapascals; and,
a module backplane attached to said back encapsulant, said module backplane having a flexural rigidity of a plate greater than or equal to 6 Newton meters.

9. The photovoltaic module structure of claim 8, wherein the transparent front encapsulant is one of a cross-linking polyolefin or ethylene-vinyl acetate.

10. The photovoltaic module structure of claim 9, wherein the back encapsulant is a polyolefin having an elastic modulus of approximately 160 MPa.

11. The photovoltaic module structure of claim 10, further comprising a top transparent film layer, on the transparent front encapsulant, having a thickness in the range of 50 to 150 μm.

12. The photovoltaic module structure of claim 11, wherein the transparent front encapsulant has a thickness of in the range of approximately 500 to 1500 μm.

13. The photovoltaic module structure of claim 12, wherein the back encapsulant has a thickness in the range of approximately 200 to 500 μm.

14. The photovoltaic module structure of claim 8, wherein the back encapsulant is a polyolefin having an elastic modulus of approximately 160 MPa.

15. The photovoltaic module structure of claim 8, further comprising a top transparent film layer, on the transparent front encapsulant, having a thickness in the range of 50 to 150 μm.

16. The photovoltaic module structure of claim 8, wherein the transparent front encapsulant has a thickness of in the range of approximately 500 to 1500 μm.

17. The photovoltaic module structure of claim 8, wherein the back encapsulant has a thickness in the range of approximately 200 to 500 μm.
